(19) United States
(12) Patent Application Publication
(10) Pub. No.: US 2014/0052392 A1
(43) Pub. Date: Feb. 20, 2014

(54) TECHNIQUE FOR MONITORING STRUCTURAL HEALTH OF A SOLDER JOINT IN NO-LEADS PACKAGES

(71) Applicant: Bar Ilan University, Ramat Gan (IL)

(72) Inventors: Joseph Barry BERNSTEIN, Hashmonaim (IL); Israel GERSHMAN, Yahud (IL)

(21) Appl. No.: 13/965,528

(22) Filed: Aug. 13, 2013

Related U.S. Application Data
(60) Provisional application No. 61/682,771, filed on Aug. 14, 2012.

(51) Int. Cl. G01R 31/04

(52) U.S. Cl. CPC G01R 31/048
USPC 702/58; 324/750.3

(57) ABSTRACT

A printed circuit board (PCB) and a system utilizing the same is presented for use in monitoring a solder joint between the PCB and a package. The PCB comprises at least one slotted pad and at least one health monitoring circuit (HMC). The slotted pad comprises a first pad connected to a ground of the PCB, and a separate second pad, both pads of the slotted pad being configured for being joined via a single solder joint to a single pad of the package. The first and second pads are connected to the HMC, the HMC comprising: a test oscillator configured for generating a known current flowing via the second pad, the solder joint, and the first pad; and a measuring unit for measuring a voltage between the first and second pads of the PCB, thereby enabling calculation of the solder joint's resistance.

### TECHNOLOGICAL FIELD

The present invention relates to the field of integrated circuits (ICs) and printed board circuits (PCBs). More specifically, the present invention relates to a technique for measuring structural health of solder joints between a PCB and no-leads package, such as a quad-flat no-leads (QFN) package.

### BACKGROUND

A package is a device which connects an integrated circuit (IC, such as a chip) to a PCB. No-leads packages are packages in which the IC's pins are in electrical connection with the package's pads (herein referred to as “component pads”), where to each component pad corresponds to and is in electrical communication with a corresponding pin of the IC. By joining the component pads to the corresponding PCB pads via solder joints, the IC can be electrically connected to the PCB. A QFN is a particular type of no-leads package. A QFN package is a near-chip-scale, plastic-encapsulated package made with a planar copper lead frame substrate. On a bottom side is of the package “component pads” are provided for being joined via solder to corresponding pads (leads) of the PCB.

Thermal cycles are the dominant failure mechanism to many IC packages. Different CTE values (coefficient thermal expansion) of the package and the substrate lead to thermo-mechanical fatigue of the solder-joints followed by development of cracks and eventually to the final fracture of the solder joints. Among no-leads packages, QFN (Quad Flat No-lead, additionally termed MLF, MLP, LFCSP, VQFN, DFN, LPCC) is a very attractive package due to its electrical and thermal performance which makes it very desirable for high speed and high power components. However the drawback of QFN package is its low reliability for thermal cycles' environment like automotive and aerospace industry. The end-of-life (EOL) of a QFN package (i.e. the time by the end of which the QFN package's electrical connection to the PCB is cut because of a fracture in the solder joint) is generally about 3 times shorter than the lifetime of a ball grid array (BGA) package (C. Tulkoff, “Manufacturing and Reliability Challenges With QFN”, CTEA (SMTA/IMAPS) Austin Expo & Tech Forum, October, 2009). Prognosis of package end-of-life does not change its reliability but in some applications it could avoid abrupt failure by scheduled maintenance or replacement of the module. In some applications it could precede catastrophic failures.

Many studies have been conducted in order to estimate useful life of electronic assemblies based on their technology and environmental stress to which they are subjected. Some prognostic and health management tools have been developed that are based on known fatigue models. These can predict useful life of materials under known loading conditions (J. Gu, M. Pecht, “Prognostics and Health Management Using Physics-of-Failure”, Reliability and Maiaintainability Symposium, 2008, p. 481-487).

Some of today's common prognostics techniques are theoretical tools rather than in-situ monitoring and tend to have large margin of error with respect to specific assemblies in the field, for example due to assembly variations and quality problems. Also, some references in the field describe a technique of material state interrogation in the field in order to determine the remaining useful life under known stress loading prior to repair or replacement. This method requires MEMS specific sensors and relies on extrapolation models for remaining life predictions (P. Lall, M. N. Islam, M. K. Rahim, J. C. Suhling, “Prognostics and Health Management of Electronic Packaging”, in IEEE Transactions on components and packaging technologies, vol. 29, no. 3, September 2006, p. 666-677).

In addition, several techniques to detect faulty solder-joints in packages are implemented in actual operational devices and packages in the field. Such techniques are described, for example, in U.S. Pat. No. 7,196,294, in US Patent Publication 2008/0144243, and in A. Bhatia, J. P. Hofmeister, J. Judkins, D. Goodman, “Advanced Testing and Prognostics of Bali Grid Array Components with a Stand-alone Monitor IC”, in IEEE Instrumentation & Measurement Magazine, August 2010, p. 42-47. These techniques require additional circuitry inside the package and can indicate failures of fully fractured solder-joints due to high resistance threshold referred to initial resistance of unaged solder-joint. Therefore, in such techniques, the package and/or IC are modified.

### GENERAL DESCRIPTION

There is therefore a need in the field for a novel technique for monitoring crack formation in the solder joints between a no-leads package (e.g. QFN package) and a PCB.

As mentioned above, in the general art, the package and/or IC are modified in order to implement a technique for monitoring crack formation. If the modification is in the IC or in the package, additional design and testing is required, in order to ensure that the modified IC works as intended. Furthermore, modifying a package to include a crack monitoring circuit may increase the cost of the package.

In the present invention, rather than modifying the IC or the package, the PCB is modified to include a health monitor configured for measuring a property of the solder joint and enable the assessment of the solder joint's structural heath. Therefore the technique of the present invention can be used with any IC having a no-leads package, regardless of the package's functionality. The health monitor includes a slotted pad and is a health monitor circuit (HMC).

In the invention, there is provided a PCB in which at least one pad is a slotted pad presenting two separate parts. That is to say, instead of joining the component pad to a single PCB pad connected to the ground of the PCB, at least one of the component pads is joined (soldered) to a pair of PCB pads. One part of the slotted PCB pad is called ground pad and is connected to the PCB's ground, while the second part of the slotted PCB pad is called the crack indicator. A health monitor circuit (HMC) located on the PCB itself is connected to the ground pad and to the crack indicator.

The health monitor circuit (HMC) generates a known current (I) travelling from the HMC to the PCB's ground via the crack indicator, the solder joint (second PCB pad), and the ground pad. The HMC measures a voltage (V) between the crack indicator and the ground pad, and enables calculation of the resistance (R) of the solder joint between the ground pad and the crack indicator via the formula R=V/I.

The resistance R of the solder joint depends on the dimensions of the solder-joint and the length of the crack. Generally, R rises as the length of the crack increases. R can therefore be related to the length of the crack via known functions.

A time profile of the resistance of the solder joint is thus indicative of a time profile of the length of the crack, and can be used to estimate the end-of-life (EOL) of the solder joint.

Optionally, each of a plurality of the PCB pads is a slotted pad. In a variant, each slotted pad is connected to a corresponding HMC. In another variant more than one slotted pads are connected to a single HMC. In such case, the PCB includes means to multiplex signals from the plurality of slotted pads to the single HMC.

The advantage of the technique of the present invention lies in the fact that the measurement of the crack's propagation is performed outside the package and IC. This is possible because the health monitor is based on the ohmic resistance measured between both parts of the slotted pad that are outside the package itself. Therefore, the package and IC need not be modified. Instead, the modification occurs on the PCB. The meaning is that this health monitor can be implemented for any integrated circuit that uses a no-leads package (e.g. QFN package), no matter what the IC's functionality is. This could be analog, field-programmable gate array (FPGA), Microcontroller or any other IC.

Therefore, an aspect of some embodiments of the present invention relates to a PCB for use in monitoring a solder joint between the PCB and a no-leads package. The PCB includes at least one slotted pad and at least one health monitoring circuit (HMC). The slotted pad includes a first pad (ground pad) connected to the ground of the PCB, and a separate second pad (crack indicator). Both pads of the slotted pad are configured for being joined via solder to a single pad of the package. The first and second pads are connected to the HMC. The HMC is configured for generating a known current flowing via the second pad, the solder joint, and the first pad, and for measuring a voltage between the first and second pads of the PCB. This enables the calculation of the solder's resistance. The solder's resistance can be used to determine the length of the crack. The change of the solder's resistance over time can be used to estimate the solder joint's end-of-life.

Optionally, the HMC's measuring unit comprises a band pass filter, an amplifier, and an analog-to-digital converter.

In a variant, a single HMC is connected to a single slotted pad. In another variant, the PCB comprises a plurality of slotted pads connected to a plurality of HMCs. In yet another variant, the PCB comprises a plurality of slotted pads multiplexed to a single HMC.

Another aspect of some embodiments of the present invention relates to a system for monitoring a solder joint between the PCB and a package. The system includes the above-mentioned PCB and a control unit. The control unit is configured for receiving the measured voltage value and the known current value from the HMC, and for using the measured voltage value and the known current value to calculate the resistance of the solder joint.

In a variant, the control unit comprises at least one module configured for using the calculated resistance of the solder joint in order to estimate a length of a crack in the solder joint.

In another variant, the control unit comprises an analysis module configured for determining at least one point in time in which the crack's length reaches a predetermined value.

In a further variant, the control unit is configured for constructing data relating to at least one of the following: the solder joint's resistance as a function of time; and a change in time of the resistance of the solder joint with respect to an initial resistance value.

Optionally, the control unit is configured for: calculating the second time derivative of the constructed data; identifying a first time point in which a maximum of the second time derivative is reached and a second time point in which a minimum of the second time derivative is reached; subtracting the first time point from the second time point; receiving simulated data which indicates the occurrence of the maximum and the minimum as percentages of a time between an initiation of the crack and a complete fracture of the solder joint; combining the simulated data with the experimentally identified first and second points to estimate a period in time in which the complete fracture will occur.

Another aspect of some embodiments of the present invention relates to a method of measuring a resistance of a solder joint between the PCB and a package. The method includes: joining at least one pad of the package to a slotted pad on a PCB via the solder joint, the slotted pad comprising a first pad connected to a ground of the PCB, and a separate second pad; generating a known current flowing via the second pad, the solder joint, and the first pad; measuring a voltage between the first pad and the second pad; dividing the measured voltage by the known current.

Another aspect of some embodiments of the present invention relates to a method for monitoring a reliability of a solder joint between a PCB and a package. The method includes: (i) performing a simulation yielding data indicative of a second time derivative of a solder joint's resistance or resistance change as a function of time; (ii) identifying a first simulated point corresponding to a maximum of the simulated second derivative and a second simulated point corresponding to a minimum of the simulated second derivative, the first and second simulated points being expressed as percentages of a time period between an initiation of a crack in the solder joint and a fracture of the solder joint due to the crack; (iii) calculating a difference between the second and first simulated points; (iv) measuring a resistance of the solder joint over time, as explained above; (v) determining a second time derivative of the measured resistance over time; (vi) identifying a third point and a fourth point corresponding respectively to a maximum and a minimum of the second derivative determined in (v), the third and fourth points being expressed in terms of time; (vii) subtracting the fifth point from the fourth point, thereby yielding a measured time period between the maximum and minimum of the second derivative determined in (v); and (viii) determining a relation between the measured time period determined in (vii) and the difference determined in (iii), and using the relation in order to calculate a fifth time point corresponding the solder joint's fracture.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1a illustrates a top view of a single pad of a PCB, for connecting to a corresponding single pad in a no-leads package, as known in the art;

FIG. 1b illustrates a top view of a slotted pad of a PCB, for connecting to a single pad in a no-leads package, according to some embodiments of the present invention;

FIG. 2 is a schematic drawing illustrating a lateral cross section of a pad of a no-leads package joined via a solder joint to a slotted PCB pad, according to the present invention;

FIG. 3 is a schematic drawing illustrating a circuit design of the health monitor's operation, according to some embodiments of the present invention;

FIG. 4 illustrates a solder-joint simulation in a finite-elements (FE) model;

FIGS. 5a and 5b are graphs illustrating simulated values of resistance change in the solder joint as function of crack length for different crack's locations along Z axis;

FIGS. 6a and 6b are graphs illustrating a first curve describing the simulated values of the resistance change in the solder joint as a function of time and a second curve describing the second derivative of the first curve, for two different cases;

FIG. 7 is a graph illustrating two first curves describing the second time derivatives of the resistance change, for the cases in which the crack propagates at 75% and 100% of the solder joint's height; and

FIG. 8 is a technical drawing illustrating a 56-pin QFN package of an ADUC845 analog microcontroller, where pads connected to suitable (e.g. power) pads have been selected for being joined to respective slotted pads in the PCB.

### DETAILED DESCRIPTION OF EMBODIMENTS

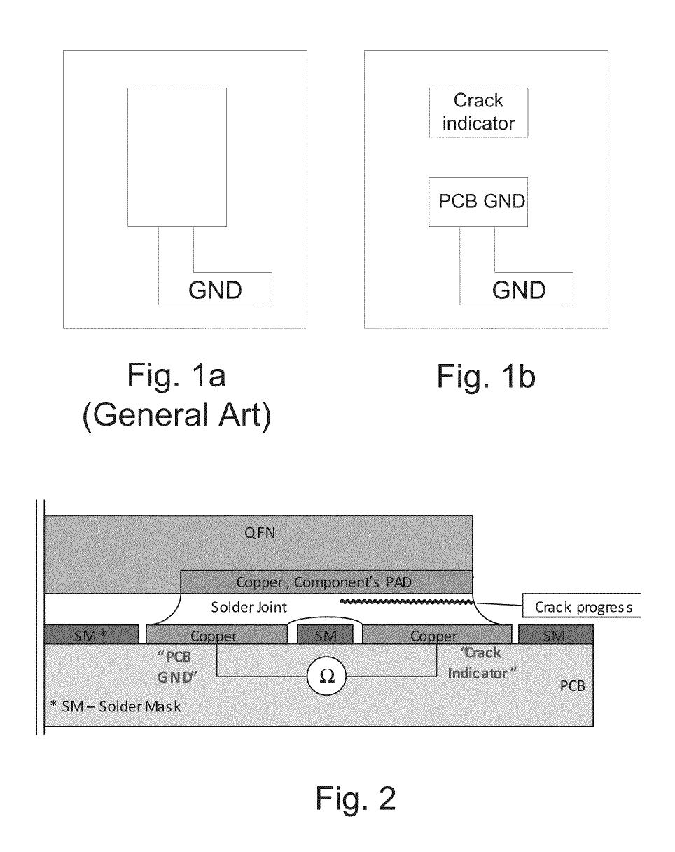

Referring now to the figures, FIG. 1a illustrates a top view of a PCB's single pad, for connecting to a corresponding single pad in a no-leads package, as known in the art; FIG. 1b illustrates a top view of a slotted pad of a PCB, for connecting to a single pad in a no-leads package, according to some embodiments of the present invention.

In the general art, each pad of the no-leads package (component pad) is configured for being joined to a single PCB pad connected to the PCB's ground. In contrast, in the present invention, the PCB includes a slotted pad configured for being joined via solder to the corresponding component pad. The slotted pad presents a pair of pads, wherein the first pad is connected to the PCB's ground, while the second pad (herein called “crack indicator”) is a separate pad. As will be seen below, this modified PCB pad allows measuring of the solder-joint's ohmic resistance.

Solder-joint resistance is affected by cracks that propagate as a result of thermo-mechanical fatigue. Changes in this solder-joint's resistance with respect to initial value are the leading indicator of crack's propagation; comparison of this change to a known pattern serves to predict the remaining lifetime. In large packages, 10-20% of total pins are power ones. This can be seen in the example of FIG. 8, in which out of 56 pins, ten pins (highlighted by circles) are power pins. Solder-joint health monitoring can be incorporated with DC-Power pins of the package without any interference to a normal operation of the IC, meaning no dedicated pins are required for this monitoring method. Therefore, the component pads corresponding to the power pins of the package are especially suitable for being joined to respective slotted pads in the PCB. The more pins are monitored in the package; the higher the confidence in prediction of the package's remaining useful life. Multiple slotted pads can be multiplexed to a central ‘Health Monitor Circuit’ without increasing the PCB real estate and power consumption. Since the fatigue effect is a relatively slow phenomenon, monitoring process frequency could be low, once a week or month what is translated to meaningless average power consumption. Alternatively, a plurality of health monitor circuits may be present in the PCB of the present invention, each health monitor circuits configured to perform measurements relating to one or more slotted pads.

FIG. 2 is a schematic drawing illustrating a lateral cross section of a pad of a no-leads package joined via a solder joint to a slotted PCB pad, according to the present invention.

A requirement of the technique of the present invention is a slotted pad on PCB side of the solder-joint. Instead of using normal dimensions of the pad as recommended by the package manufacturer, the longitudinal size of the slotted pad is divided into two parts. Transversal dimension is without change. One part (PCB ground pad) serves as it was designated for normal operation, GND for example, and second part of the pad serves as a ‘Crack Indicator’. Ohmic resistance is measured between these both pads by an ohmmeter Q. The ohmmeter is part of the health monitoring circuit (HMC) that will be described later. Based on finite-elements (FE) simulations and experimental results, the resistance of unaged ‘Crack Indicator’ (with respect to GND) is ˜800μΩ. This resistance will monotonically increase as a function of the crack's progress. The experimental results can be found in “I. Gershman, J. B. Bernstein, “Solder-joint Quantitative Crack Analysis—ohmic resistance approach”, IEEE Transactions on components, packaging and manufacturing technologies, 10.1109/TCPMT.2012.2188894”.

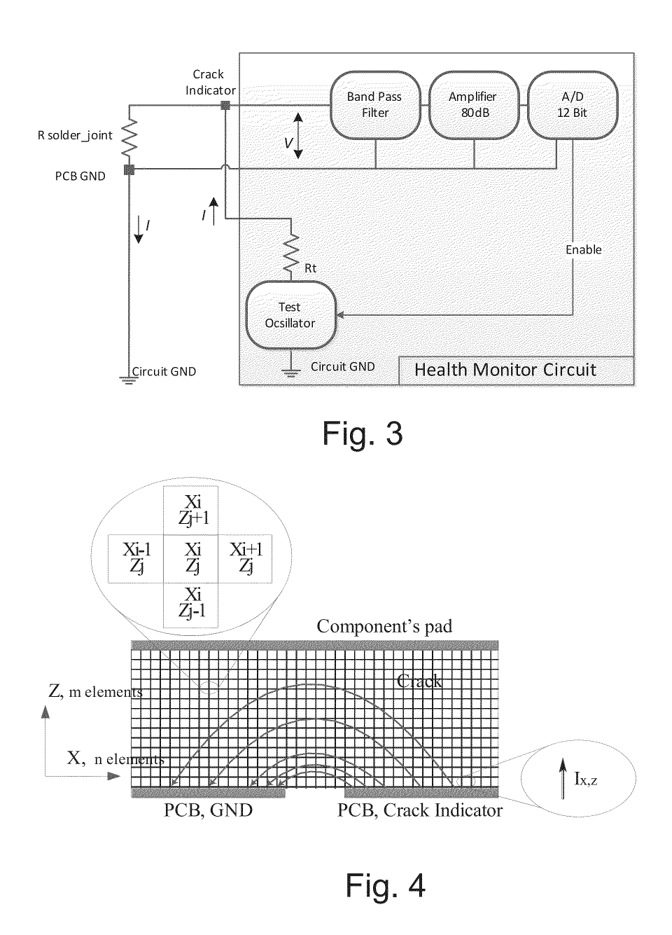

FIG. 3 is a schematic drawing illustrating a circuit design of the health monitor's operation, according to some embodiments of the present invention.

The health monitoring circuit (HMC) is located on the PCB and connected by leads within the PCB to the ground pad and to the crack indicator. In operation, the ground pad and the crack indicator are joined by a solder joint having a certain resistance (“R_solder_joint”). The HCM includes a test oscillator, an Amplifier, a Filter and an analog-to-digital converter (A/D), and is configured for effecting voltage and current measurements in order to enable calculation of the solder joint's resistance.

In order to measure this resistance the HMC sources a current (I) through the “R_solder_joint” and the voltage across this resistance (V) is measured by 3 elements: Amplifier, Filter and A/D. The use of these three elements for voltage measurement is common in the art. The current I generated by the test oscillator is equal to the amplitude of the “test oscillator” voltage divided by the sum of Rₜ and R_{solder}_{_{—}}ⱼₒᵢₙₜ. The Rₜ value is chosen to be about 5 orders of magnitude larger than that of R_{solder}_{_{—}}ⱼₒᵢₙₜ, so it can be assumed for any practical matter that I is constant even though R_{solder}_{_{—}}ⱼₒᵢₙₜ resistance increases as a function of the crack size, and therefore I is substantially independent of the R_{solder}_{_{—}}ⱼₒᵢₙₜ. V, on the other hand, depends on R_{solder}_{_{—}}ⱼₒᵢₙₜ. Therefore, after determining the constant and known value of I, and measuring V, R_{solder}_{_{—}}ⱼₒᵢₙₜ can be calculated as a ratio V/I.

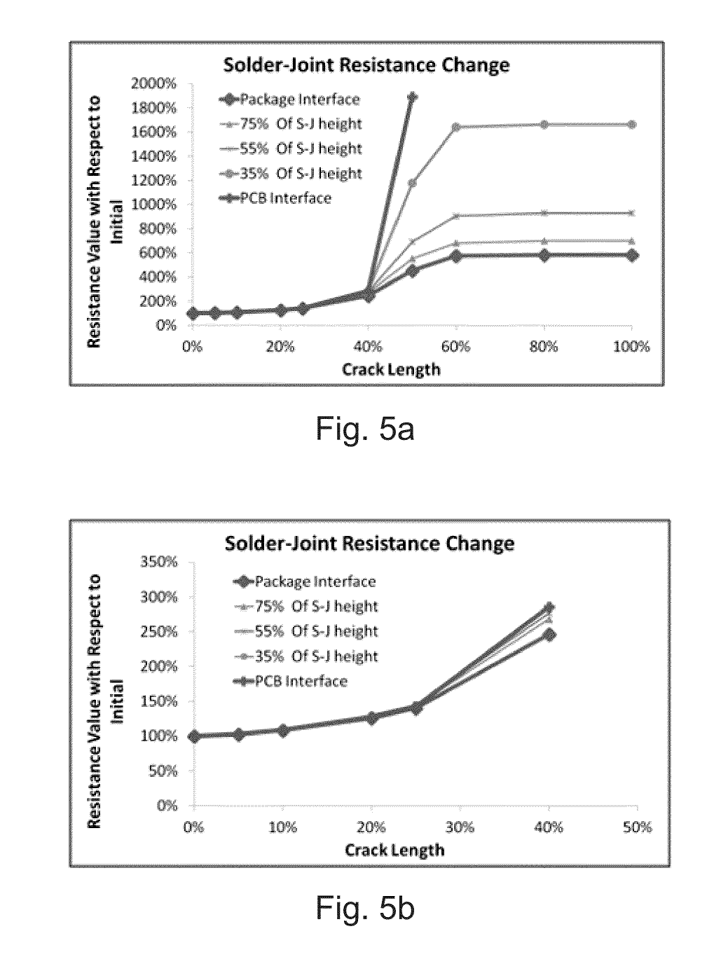

FIGS. 4, 5a, and 5b relate to a simulation made by the inventors to show that as long as the crack's length is below a certain value, the crack's length can be estimated by the technique of the present invention, no matter what the crack's distance from the component is.

FIG. 4 illustrates a solder-joint simulation in FE model, which was used in order to calculate the resistance changes in solder-joint with a crack presence. The solder-joint was reduced to two-dimensional model and divided into 5000 sub-elements when the relationship between adjacent elements was calculated using the two-dimensional Laplace equation:

∇²V(x,z)=0

The ohmic resistance was calculated by considering a hypothetical voltage source applying a voltage between the PCB's ground pad (“PCB, GND”) and the PCB's ground indicator (“PCB, Crack Indicator”). Using Laplace's equation, the voltage of each of the 5000 sub-elements is calculated, enabling the calculation of the current between both sides of the voltage source. The resistance therefore is the division between the voltage applied by the voltage source and the current.

FIGS. 5a and 5b are graphs illustrating simulated values of resistance change in the solder joint as function of crack length for different crack's locations along Z axis. The graph of FIG. 5b is a detail of the graph of FIG. 5a.

The simulation was performed for various values of crack's length and several locations of the crack along Z axis, between the PCB (Z=0) and the bottom side of the package. In FIG. 4, the crack's size along the X axis is 50% of the maximal crack length, and the crack is located near the component's bottom side. The ohmic resistance between ‘Crack Indicator pad’ and ‘PCB GND pad’ increases monotonically along with the crack's propagation along the X axis. Its final resistance value, after a full fracture occurrence of the solder-joint, depends on the crack's vertical location as it can be seen in FIGS. 5a and 5b. There is a singular case when the crack propagates along PCB interfaces. In such case the resistance will eventually reach infinity when the solder-joint is fully fractured (the line labeled as ‘PCB Interface’ in). In all other cases (different vertical locations of the crack), the resistance between ‘Crack Indicator pad’ and ‘PCB GND pad’ reaches finite value even though the solder-joint is fully fractured. An interesting fact in the resistance change curves in FIGS. 5a and 5b is that while final resistance (i.e. the resistance at the solder joint's fracture) strongly depends on the crack's location along Z axis, the resistance changes are almost identical for different locations of the fracture in the Z axis, as long as the crack's is shorter than 30%.

Also, it can be seen that in the region near the interface between the solder joint and the package, the variance of solder joint's resistance change caused by the variance in the crack's vertical position is relatively small, even when the crack is longer than 30% of its maximum length. Therefore, a FE simulation of a crack propagating along an axis that is in the vicinity of the interface between the solder joint and the package provides a good estimate of the resistance of the solder joint as long as the solder joint's vertical location is between 75% and 100% of the solder joint's height.

The inventors have found that, in most cases, cracks occur and propagate in the vicinity of this interface. In view of the above, therefore, a FE simulation of a crack propagating near the interface between the solder joint and the package can accurately estimate the solder joint's resistance change as a function on the crack's length in the field. This fact can be used in order to estimate the crack's length (based on a measured resistance thereof) and by that predicting end-of-life of the package, without having to measure the vertical location of the crack.

The simulations presented in FIGS. 5S and 5b were performed for following solder-joint dimensions: solder-joint height=10% of component's pad length, ‘Crack Indicator pad’ and ‘PCB GND pad’ lengths=45% of component's pad length.

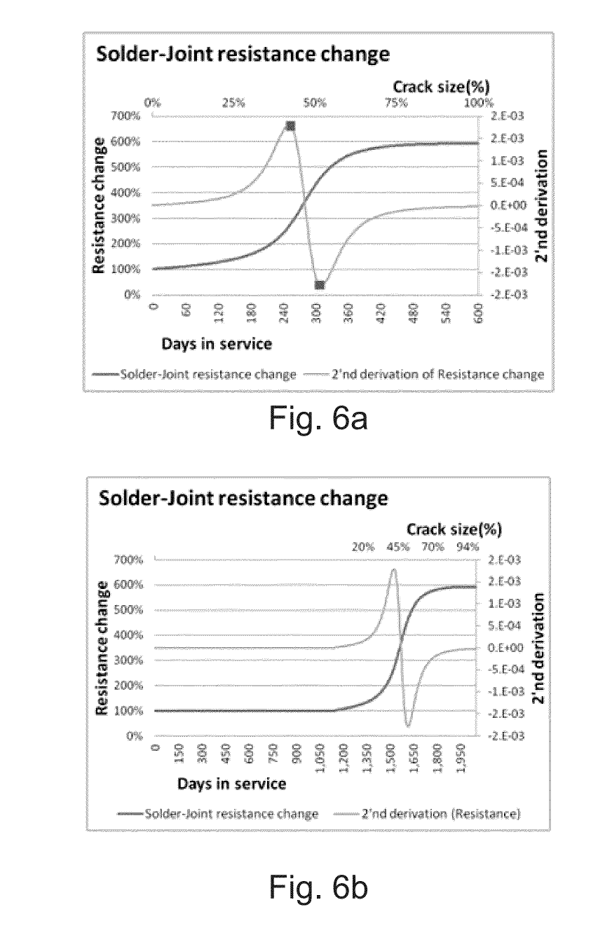

FIGS. 6a and 6b are graphs illustrating a first curve describing the simulated values of the resistance change in the solder joint as a function of time and a second curve describing the second derivative of the first curve, for two different cases.

Once the health monitor of the present invention is implemented and data is collected on a frequent basis, the health of monitored solder-joints could be evaluated. The data points corresponding to the measured solder-joint's resistance can be analyzed in order to estimate the end-of-life of specific solder-joint. N₀ is the number of cycles at which the crack in the solder-joint initiates and N_{f} is the number of cycles at which full solder-joint fracture occurs. There are cases where solder-joints can be partially cracked at day one, immediately after soldering the no-leads package, while in other cases the crack starts after certain period in the field. Since the model used in the present technique deals with the connection between the crack size and solder-joint's measured resistance, the resistance change curve could be translated into crack length (in % of the maximal crack length).

It should be noted that in field applications thermal cycles are not counted. Rather, it is assumed that there is a correlation between time and thermal cycles, so all the analysis is based on time scale (e.g., hours, days, months or years). This means that N₀ and N_{f} can be expressed in terms of time.

In order to estimate solder-joint's end-of-life, the initiation point (N₀) and crack propagation are to be extracted from the resistance change curve. However, the exact time of crack initiation cannot be accurately determined from the resistance change curve. Therefore, the inventors have found that a suitable manner for analyzing the resistance change curve is by studying the second derivative of the resistance change curve. This operation provides two distinct and easily identifiable points for EOL estimation: a maximum and a minimum of the second derivative of the resistance change curve, as seen in FIGS. 6a and 6b. The time points from N₀ at which the maximum and minimum of the second derivative curve occur depend on the geometry of the component pad, the slotted pad, and the solder joint, and are always constant, no matter where N₀ is. Different set of dimensions will require appropriate FE simulations for resistance/crack size curves. For example, in the case where the solder-joint height is 10% of component's pad length, and ‘Crack Indicator pad’ and ‘PCB GND pad’ lengths are each 45% of component's pad length, the maximum of the second derivative curve is always found at about 42% of the maximal crack length and the minimum of the second derivative curve is always found at about 52% of the maximal crack length.

Using the fact that the crack's propagation rate is constant (as shown, for example in “I. Gershman, J. B. Bernstein, “Solder-joint Quantitative Crack Analysis—ohmic resistance approach”, IEEE Transactions on components, packaging and manufacturing technologies, 10.1109/TCPMT.2012.2188894”), the values of the crack's length in percentage of the maximal crack length can be translated into values of time as a percentage of the time between N₀ and N₁ (where N_{f} corresponds to EOL). Therefore, the resistance measurements of the device of FIG. 3 can be used to construct a time profile of the solder joint's resistance change, enabling the calculation of the second derivative curve thereof. On such experimentally-determined second derivative curve, the minimum and maximum are easily identified, and the time points in which they occur are recorded. Then, the time at which the maximum occurs is subtracted from the time at which the minimum occurs. This difference corresponds to the difference of the percentages of the time between N₀ and N_{f} determined via the simulation. Knowing that a certain length of time (measured experimentally) corresponds to a certain percentage of the time between N₀ and N_{f} (determined via FE simulation), and knowing that the minimum or maximum of the second derivative curve occurred at a certain (simulated) percentages of the time between N₀ and N_{f}, N_{f} can be determined. Because N_{f} is the time point at which the full fracture of the solder joint occurs, N_{f} corresponds to the estimated EOL of the package.

Returning to our previous example, if the difference in time between the minimum and maximum of the second derivative curve is experimentally determine to be 100 days, then 100 days correspond to (52%-42%) of the time period between N₀ and N_{f}, i.e. 10%. Therefore knowing the time left from the minimum to N_{f} is (100%−52%)=48%, we can estimate that that EOL will occur 480 days after the minimum of the second derivative curve has been reached.

Two different cases of solder cracking are presented in FIGS. 6a and 6b. The example of FIG. 6a simulates cracking that starts on day 1 (the first day of operation) and reaches full fracture after 600 days (N₀=0, N_{f}=600 days). The example of FIG. 6b simulates cracking that starts after 1100 days of use and fractures after 2000 days (N₀=1100, N_{f}=2000 days). Crack's propagation rates are different in both cases as well as initiation point. For both cases, however, the second derivative curve's maximum is around 42% of the maximal crack size and the second derivative curves maximum is around 52% of the maximal crack size.

It should be noted that the times points (cycles) at which the maximum and minimum of the second derivative of the resistance change curve are reached are dependent on the crack's vertical location. However, as indicated above (in FIGS. 5a and 5b), the resistance change curve (and consequently the second derivative thereof) does not vary much for different vertical locations of the crack, as long as the crack is in the vicinity of the interface between the solder joint and the package. Because most cracks occur and propagate, near this interface, the analysis of the second derivative curve can be used to estimate EOL, without having to take measure the vertical location of the crack.

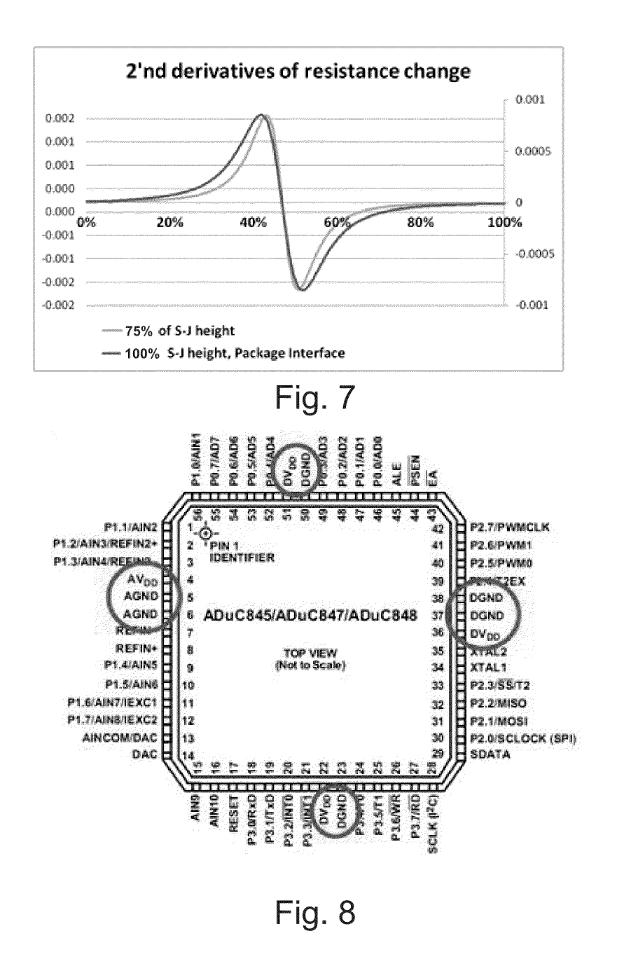

To demonstrate this fact, the inventors have conducted as simulation to determine how the vertical crack site affects the location of the peaks (maximum and minimum) of the second derivative curve of the resistance change. The results of this simulation can be seen in FIG. 7. As it was stated earlier, the vertical crack location is usually in the vicinity of the package pad, near the IMC layer. However, real cracks are never zero-thickness planes, and generally sport some roughness and variations along vertical axis. In order to check the sensitivity of the technique of the present invention to the change in vertical location of the crack, a comparison between second derivative curves corresponding to two vertical locations of the cracks was performed. In first case the crack propagates along the package interface (100% of the solder joint's height) and in second case it propagates at 75% of the solder joint's height, along the solder bulk. As FIG. 7 demonstrates, the location of the center and the distance between the peaks in the two second derivative curves remained almost the same, notwithstanding the variation of the vertical location of the crack. Therefore, the technique of the present invention can be used to estimate EOL, without having to take measure the vertical location of the crack, and without having to consider the roughness and change of propagation of the crack.

1. A printed circuit board (PCB) for use in monitoring a solder joint between the PCB and a package, the PCB comprising at least one slotted pad and at least one health monitoring circuit (HMC), wherein:
the slotted pad comprises a first pad connected to a ground of the PCB, and a separate second pad, both pads of the slotted pad being configured for being joined via a single solder joint to a single pad of the package;
the first and second pads are connected to the HMC, the HMC comprising: a test oscillator configured for generating a known current flowing via the second pad, the solder joint, and the first pad; and a measuring unit for measuring a voltage between the first and second pads of the PCB, thereby enabling calculation of the solder joint's resistance.

2. The PCB of claim 1, wherein the HMC's measuring unit comprises a band pass filter, an amplifier, and an analog-to-digital converter.

3. The PCB of claim 1, wherein a single HMC is connected to a single slotted pad.

4. The PCB of claim 2, wherein a single HMC is connected to a single slotted pad.

5. The PCB of claim 1, comprising a plurality of slotted pads connected to a plurality of HMCs.

6. The PCB of claim 2, comprising a plurality of slotted pads connected to a plurality of HMCs.

7. The PCB of claim 1, comprising a plurality of slotted pads multiplexed to a single HMC.

8. The PCB of claim 2 comprising a plurality of slotted pads multiplexed to a single HMC.

9. A system for monitoring a solder joint between a PCB and a package, comprising:
the PCB of claim 1; and
a control unit for receiving the measured voltage value and the known current value from the HMC, and for using the measured voltage value and the known current value to calculate the resistance of the solder joint.

10. The system of 9, wherein the control unit comprises at least one module configured for using the calculated resistance of the solder joint in order to estimate a length of a crack in the solder joint.

11. The system of claim 9, wherein the control unit comprises an analysis module configured for determining at least one point in time in which a length of a crack in the solder joint reaches a predetermined value.

12. The system of claim 10, wherein the control unit comprises an analysis module configured for determining at least one point in time in which the crack's length reaches a predetermined value.

13. The system of claim 9, wherein the control unit is configured for constructing data relating to at least one of the following:
the solder joint's resistance as a function of time; and
a change in time of the resistance of the solder joint with respect to an initial resistance value.

14. The system of claim 13, wherein the control unit is configured for:
calculating the second time derivative of the constructed data;
identifying a first time point in which a maximum of the second time derivative is reached and a second time point in which a minimum of the second time derivative is reached;
subtracting the first time point from the second time point;
receiving simulated data which indicates the occurrence of the maximum and the minimum as percentages of a time between an initiation of the crack and a complete fracture of the solder joint;
combining the simulated data with the experimentally identified first and second points to estimate a period in time in which the complete fracture will occur.

15. A method of measuring a resistance of a solder joint between the PCB and a package, the method comprising:
joining at least one pad of the package to a slotted pad on a PCB via the solder joint, the slotted pad comprising a first pad connected to a ground of the PCB, and a separate second pad;
generating a known current flowing via the second pad, the solder joint, and the first pad;
measuring a voltage between the first pad and the second pad;
dividing the measured voltage by the known current.

16. A method for monitoring a reliability of a solder joint between a PCB and a package, the method comprising:
i. performing a simulation yielding data indicative of a second time derivative of a solder joint's resistance or resistance change as a function of time;
ii. identifying a first simulated point corresponding to a maximum of the simulated second derivative and a second simulated point corresponding to a minimum of the simulated second derivative, the first and second simulated points being expressed as percentages of a time period between an initiation of a crack in the solder joint and a fracture of the solder joint due to the crack;
iii. calculating a difference between the second and first simulated points;
iv. measuring a resistance of the solder joint over time, according to the method of claim 11;
v. determining a second time derivative of the measured resistance over time;
vi. identifying a third point and a fourth point corresponding respectively to a maximum and a minimum of the second derivative determined in (v), the third and fourth points being expressed in terms of time;
vii. subtracting the fourth point from the third point, thereby yielding a measured time period between the maximum and minimum of the second derivative determined in (v);
viii. determining a relation between the measured time period determined in (vii) and the difference determined in (iii), and using the relation in order to calculate a fifth time point corresponding the solder joint's fracture.
